(19) United States
(12) Patent Application Publication
(10) Pub. No.: US 2026/0291408 A1
(43) Pub. Date: Sep. 24, 2026

(54) ELECTROSTATIC CHUCK DEVICE

(71) Applicant: SUMITOMO OSAKA CEMENT CO., LTD., Tokyo (JP)

(72) Inventors: Yuki KINPARA, Tokyo (JP); Taku ICHIYOSHI, Tokyo (JP); Satoyoshi INUI, Tokyo (JP); Toru SUGAMATA, Tokyo (JP)

(73) Assignee: SUMITOMO OSAKA CEMENT CO., LTD., Tokyo (JP)

(21) Appl. No.: 19/168,318

(22) PCT Filed: Apr. 5, 2024
(86) PCT No.: PCT/JP2024/014186

§ 371 Date: Sep. 23, 2025

(30) Foreign Application Priority Data
Apr. 14, 2023 (JP) 2023-066281

(51) Int. Cl. H02N 13/00; H10P 72/72

(52) U.S. Cl. CPC H02N 13/00; H10P 72/722

(57) ABSTRACT

An electrostatic chuck device includes: a plate-shaped electrostatic chucking portion and a base portion that has a disk shape around a central axis and that supports the electrostatic chucking portion on a support surface of the base portion. A refrigerant channel that extends along the support surface is provided inside the base portion. The refrigerant channel has a first channel portion that is formed around at least one through-hole penetrating the base portion in an axial direction of the central axis at an interval from the through-hole on an outer side in a hole diameter direction of the through-hole, and a second channel portion that is located on both sides of the first channel portion in an extension direction of the refrigerant channel. A channel cross-sectional area of the first channel portion is smaller than a channel cross-sectional area of the second channel portion.

### TECHNICAL FIELD

The present invention relates to an electrostatic chuck device.

This application claims priority based on Japanese Patent Application No. 2023-066281 filed on Apr. 14, 2023, the content of which is incorporated herein by reference.

### BACKGROUND

In semiconductor manufacturing apparatuses using plasma, such as plasma etching apparatuses and plasma CVD apparatuses, an electrostatic chuck device is used as a device for easily attaching and fixing a wafer to a placement surface and maintaining the wafer at a desired temperature. Patent literature No. 1 discloses a structure having a plate-shaped ceramic body including a placement surface and a base member provided with a cooling passage through which a cooling medium flows.

### CITATION LIST

### Patent Literature

Patent Literature No. 1: Japanese Laid-open Patent Publication No. 2007-035878

### SUMMARY OF INVENTION

### Technical Problem

In recent years, devices using semiconductors tend to be highly integrated. Therefore, when manufacturing devices, wiring microfabrication technology and three-dimensional mounting technology are required. In carrying out such processing technology, the semiconductor manufacturing apparatus is required to reduce the in-plane temperature distribution (temperature difference) of a wafer. In the related field, the inplane temperature distribution of the wafer may not be reduced to the desired temperature difference, and an improvement has been desired.

The present invention has been made under these circumstances, and an object of the present invention is to provide an electrostatic chuck device with high temperature uniformity.

### Solution to Problem

The present invention provides an electrostatic chuck device including: a plate-shaped electrostatic chucking portion that has a placement surface on which a plate-shaped sample is placed and that has an electrostatic attraction electrode provided therein; and a base portion that has a disk shape around a central axis and that supports the electrostatic chucking portion from a side opposite to the placement surface on a support surface of the base portion, in which the base portion has a through-hole that penetrates the base portion in an axial direction of the central axis, and a refrigerant channel that is provided inside the base portion and extends along the support surface, the refrigerant channel has a first channel portion that is formed at an interval on an outer side in a hole diameter direction around the through-hole, and a second channel portion that is located on both sides of the first channel portion in an extension direction of the refrigerant channel, and a channel cross-sectional area of the first channel portion is smaller than a channel cross-sectional area of the second channel portion.

That is, the present invention includes the following inventions [1] to [8].

It is also preferable to combine two or more of the following inventions as necessary.
[1] An electrostatic chuck device including: a plate-shaped electrostatic chucking portion that has a placement surface on which a plate-shaped sample is placed and that has an electrostatic attraction electrode provided therein; and a base portion that has a disk shape around a central axis and that supports the electrostatic chucking portion from a side opposite to the placement surface on a support surface of the base portion, in which the base portion has at least one through-hole that penetrates the base portion in an axial direction of the central axis, and a refrigerant channel that is provided inside the base portion and extends along the support surface, the refrigerant channel has a first channel portion, and a second channel portion that is coupled to both ends of the first channel portion, the first channel portion is formed on an outer side in a hole diameter direction of the through-hole around the through-hole at an interval from the through-hole, the second channel portion is located on both sides of the first channel portion in an extension direction of the refrigerant channel, and a channel cross-sectional area of the first channel portion is smaller than a channel cross-sectional area of the second channel portion.
[2] The electrostatic chuck device according to [1], in which the first channel portion has a smaller width dimension in a direction intersecting the axial direction and the extension direction than the second channel portion.
[3] The electrostatic chuck device according to [1] or [2], in which the channel cross-sectional area of the first channel portion is 0.5 times or more and less than 1.0 times the channel cross-sectional area of the second channel portion.
[4] The electrostatic chuck device according to any one of [1] to [3], in which the first channel portion has a first inner surface and a second inner surface that face each other, the first inner surface is formed on the outer side in the hole diameter direction of the through-hole at an interval from the through-hole and faces the outer side in the hole diameter direction, the second inner surface is formed on the outer side in the hole diameter direction with respect to the first inner surface at an interval from the first inner surface and faces the inner side in the hole diameter direction, and the first inner surface is formed in an arc shape formed concentrically with a hole inner peripheral surface of the through-hole.
[5] The electrostatic chuck device according to [4], in which the second inner surface is formed in an arc shape formed concentrically with the hole inner peripheral surface of the through-hole.
[6] The electrostatic chuck device according to [5], in which the first inner surface and the second inner surface are formed in a range of 20° to 300° around the through-hole as viewed in the axial direction.
[7] The electrostatic chuck device according to any one of [4] to [6], in which in the second channel portion that is located on at least one side of the first channel portion in the extension direction of the refrigerant channel, a connection surface curved in an arc-shape as viewed in the axial direction is formed between an inner surface of the second channel portion connected to the first inner surface and the first inner surface.
[8] The electrostatic chuck device according to any one of [4] to [7], in which a thickness of a wall portion formed between an inner peripheral surface of the through-hole and the first inner surface is 1 mm or more and 10 mm or less.
[9] The electrostatic chuck device according to any one of [1] to [8], in which the refrigerant channel has a continuous spiral shape in plan view, the base portion further includes a wall portion that partitions the refrigerant channel, the through-hole is circular in plan view and penetrates at least a part of the wall portion in the axial direction, the wall portion includes a first portion in which the through-hole is provided and a second portion which is located on both sides of the portion and in which no through-hole is provided, a width of the first portion is larger than a width of the second portion in plan view, the width of the first portion varies gradually, and a side surface of the first portion forms an inner surface of the first channel, and a side surface of the second portion forms an inner surface of the second channel.

### Advantageous Effects of Invention

According to the present invention, it is possible to provide an electrostatic chuck device with high temperature uniformity.

### BRIEF DESCRIPTION OF DRAWINGS

FIG. 1 A schematic cross-sectional view showing an example of an electrostatic chuck device according to an embodiment.

FIG. 2 A schematic plan view showing an example of a refrigerant channel of the embodiment.

FIG. 3 A schematic view showing an example of a first channel portion formed around a through-hole and a second channel portion in the refrigerant channel of the embodiment.

FIG. 4 A schematic cross-sectional view showing an example of the first channel portion formed around the through-hole and the second channel portion in the refrigerant channel of the embodiment.

FIG. 5 A diagram illustrating an event occurring around a through-hole during processing in the refrigerant channel of the embodiment.

FIG. 6 A schematic plan view showing a refrigerant channel in a modification example of the embodiment.

### DESCRIPTION OF EMBODIMENTS

Hereinafter, preferred examples of an electrostatic chuck device according to the present embodiment will be described with reference to the drawings. In all of the following drawings, dimensions, ratios, and the like of the components may be appropriately different from the actual ones in order to easily understand the drawings.

In addition, the present embodiment is simply a specific description for better understanding of the gist of the invention and does not limit the present invention unless particularly otherwise described. For example, unless otherwise specified, conditions such as materials, amounts, types, numbers, sizes, shapes, ratios, and temperatures may be changed, added, and omitted as necessary. Preferable examples may be exchanged or shared between embodiments to be described below.

In the present specification, “the degree of in-plane temperature distribution (temperature difference) of the electrostatic chucking portion (or placement surface)” may be referred to as “temperature uniformity”. The term “high temperature uniformity” means that the in-plane temperature distribution of the region of the placement surface of the electrostatic chucking portion on which the plate-shaped sample is placed is small.

### Embodiment

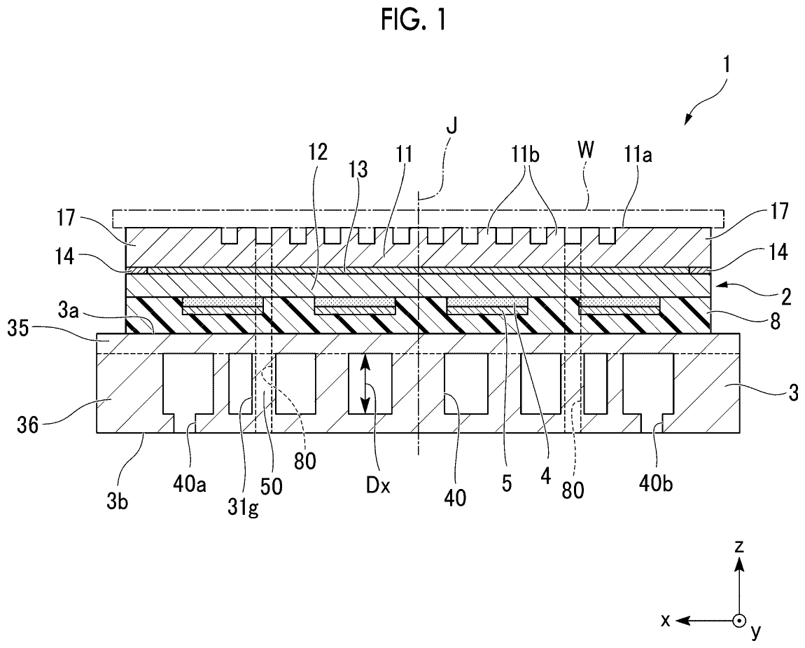

FIG. 1 is a cross-sectional view showing a preferable example of the electrostatic chuck device according to the embodiment.

The electrostatic chuck device 1 has a plate-shaped electrostatic chucking portion 2, a heater element 5, and a disk-shaped base portion 3. The electrostatic chuck device 1 has a disk shape around a central axis J. The electrostatic chucking portion 2, the heater element 5, and the base portion 3 are laminated in this order in the axial direction of the central axis J.

In the following description, the direction of each portion of the electrostatic chuck device 1 around the central axis J will be described. In the following description, the axial direction of the central axis J may be simply referred to as the “axial direction”, the radial direction around the central axis J may be simply referred to as the “radial direction,” and the circumferential direction around the central axis J may be simply referred to as the “circumferential direction” . In addition, in the following description, the up-down direction of each portion is defined by a posture in which the direction in which the central axis J extends is made to coincide with the up-down direction. However, the posture during use of the electrostatic chuck device 1 is not limited.

### Electrostatic Chucking Portion

The electrostatic chucking portion 2 includes a placement plate 11 of which an upper surface is a placement surface 11a for placing a circular plate-shaped sample W such as a semiconductor wafer, a supporting plate 12 that is integrated with the placement plate 11 and supports the bottom portion side of the placement plate 11, an electrostatic attraction electrode 13 provided between the placement plate 11 and the supporting plate 12, and an insulating material layer 14 that insulates the periphery of the electrostatic attraction electrode 13. That is, the electrostatic chucking portion 2 has the placement surface 11a on which the plate-shaped sample W is placed and has the electrostatic attraction electrode 13 provided therein.

The placement plate 11 and the supporting plate 12 are disk-shaped members having the same overlapping surface shape. The placement plate 11 and the supporting plate 12 are made of a ceramic sintered body having mechanical strength and durability against corrosive gas and its plasma. The placement plate 11 and the supporting plate 12 will be described below in detail.

A plurality of protruding portions 11b having a diameter smaller than the thickness of the plate-shaped sample are formed at predetermined intervals on the placement surface 11a of the placement plate 11, and these protruding portions 11b support the plate-shaped sample W.

A peripheral wall 17 is formed along the peripheral edge of the placement surface 11a. The peripheral wall 17 is formed at the same height as the protruding portion 11b, and supports the plate-shaped sample W together with the protruding portions 11b.

The electrostatic attraction electrode 13 is used as an electrostatic chucking electrode for generating an electric charge and fixing the plate-shaped sample W by electrostatic attraction force. The shape and size of the electrostatic attraction electrode 13 are appropriately adjusted according to its use.

The electrostatic attraction electrode 13 can be made of any material selected. For example, the electrostatic attraction electrode 13 is preferably made of conductive ceramics such as aluminum oxide-tantalum carbide (Al₂O₃—Ta₄C₅) conductive composite sintered body, aluminum oxide-tungsten (Al₂O₃—W) conductive composite sintered body, aluminum oxide-silicon carbide (Al₂O₃—SiC) conductive composite sintered body, aluminum nitride-tungsten (AlN—W) conductive composite sintered body, aluminum nitride-tantalum (AlN—Ta) conductive composite sintered body, and yttrium oxide-molybdenum (Y₂O₃—Mo) conductive composite sintered body, or refractory metals such as tungsten (W), tantalum (Ta), and molybdenum (Mo).

The electrostatic attraction electrode 13 can be easily formed by a film forming method such as a sputtering method or a vapor deposition method, or a coating method such as a screen printing method.

The insulating material layer 14 surrounds the electrostatic attraction electrode 13 to protect the electrostatic attraction electrode 13 from the corrosive gas and its plasma. In addition, the insulating material layer 14 joins and integrates a boundary portion between the placement plate 11 and the supporting plate 12, that is, an outer peripheral region other than the electrostatic attraction electrode 13. The insulating material layer 14 is made of an insulating material having the same composition or the same main component as the material forming the placement plate 11 and the supporting plate 12.

### Heater Element

The heater element 5 heats the electrostatic chucking portion 2. The heater element 5 is disposed on the lower surface side of the electrostatic chucking portion 2.

Any structure and material of the heater element 5 can be selected. For example, the heater element 5 is obtained by processing a non-magnetic metal thin plate having a constant thickness of 0.2 mm or less and preferably about 0.1 mm into a desired heater shape, for example, a shape in which a conductive thin plate in a belt shape is meandered and the entire contour is an annular shape, or the like. As the non-magnetic metal thin plate, for example, a titanium (Ti) thin plate, a tungsten (W) thin plate, a molybdenum (Mo) thin plate, and the like can be used. In order to form the heater element 5 in a predetermined heater shape, for example, a photolithography method or laser processing is used.

The heater element 5 may be provided by processing and molding the surface of the electrostatic chucking portion 2 after bonding a non-magnetic metal thin plate to the electrostatic chucking portion 2. The heater element 5 which is separately processed and molded at a position different from the electrostatic chucking portion 2 may be provided on the surface of the electrostatic chucking portion 2 by transfer printing.

The heater element 5 is bonded and fixed to the bottom surface of the supporting plate 12 with a sheet-like or film-like adhesive 4 made of silicone resin, acrylic resin, or the like having uniform thickness, heat resistance, and insulating properties.

The electrostatic chucking portion 2 and the base portion 3 are bonded via an adhesive layer 8 provided between the electrostatic chucking portion 2 and the base portion 3. The adhesive layer 8 is formed of, for example, a hardened body obtained by heating and hardening a silicone-based resin composition or an acrylic resin. The adhesive layer 8 is preferably formed by, for example, disposing a resin composition having flowability between the electrostatic chucking portion 2 and the base portion 3 and then heating and hardening the resin composition. Accordingly, the unevenness between the electrostatic chucking portion 2 and the base portion 3 is filled with the adhesive layer 8, and voids and defects are less likely to occur in the adhesive layer 8.

Therefore, the thermal conductivity of the adhesive layer 8 can be made uniform in the plane, and the temperature uniformity of the electrostatic chucking portion 2 can be improved.

### Base Portion

The base portion 3 cools the electrostatic chucking portion 2. The base portion 3 has a disk shape around the central axis J. The base portion 3 has a support surface 3a that supports the electrostatic chucking portion 2, and a bottom surface 3b that faces the opposite side of the support surface 3a. The electrostatic chucking portion 2 supports the electrostatic chucking portion 2 on the support surface 3a from the opposite side of the placement surface 11a.

The material for forming the base portion 3 is not particularly limited as long as the material is a metal having excellent thermal conductivity, electrical conductivity, and workability, or a compound material containing these metals. For example, aluminum (Al), aluminum alloys, copper (Cu), titanium (Ti), copper alloys, stainless steel (SUS), and the like are preferably used. At least a surface of the base portion 3 exposed to plasma is preferably subjected to an anodizing treatment, or an insulating film such as alumina is preferably formed thereon.

A refrigerant channel 40 through which refrigerant flows is provided inside the base portion 3. The refrigerant channel 40 is provided with an inflow port 40a for drawing the refrigerant into the refrigerant channel 40 from the outside of the base portion 3, and an outflow port 40b for discharging the refrigerant in the refrigerant channel 40 to the outside of the base portion 3. The inflow port 40a and the outflow port 40b are open in the bottom surface 3b of the base portion 3. In FIG. 1, the radial positions of the inflow port 40a and the outflow port 40b are schematically shown, and do not represent the actual arrangement.

The refrigerant channel 40 extends along the support surface 3a. That is, the refrigerant channel 40 extends along a plane perpendicular to the central axis J. The refrigerant channel 40 has a rectangular channel cross section over the entire length. In the refrigerant channel 40 of the present embodiment, an axial dimension Dx (depth) of the refrigerant channel 40 is uniform over the entire length of the refrigerant channel 40. The refrigerant channel 40 has an upper member 35 and a lower member 36. That is, the refrigerant channel 40 may be formed of the upper member 35 and the lower member 36. The upper member 35 is a plate-shaped member whose thickness direction is the axial direction. In addition, the lower member 36 is a plate-shaped member having a greater thickness dimension in the axial direction than the upper member 35.

The upper surface of the lower member 36 is provided with a recessed groove 31g that is open upward. A portion of the lower member 36 between the recessed grooves 31g forms a wall portion 50. That is, the base portion 3 has the wall portion 50. The wall portion 50 partitions the recessed grooves 31g. In addition, the lower member 36 has an outer peripheral portion (outer edge portion) that surrounds the wall portion 50 and the groove portion 31g and is coupled to a part of the wall portion 50. It is preferable that the outer peripheral portion has a constant thickness and at least a part thereof has an annular shape or a substantially annular shape in plan view.

The opening of the recessed groove 31g is covered with the upper member 35. The refrigerant flows in a region surrounded by the inner surface of the recessed groove 31g of the lower member 36 and the upper member 35. That is, the refrigerant channel 40 is formed in a region surrounded by the inner surface (bottom surface and two side surfaces facing each other) of the recessed groove 31g and the lower surface of the upper member 35. In addition, the wall portion 50 radially partitions the refrigerant channel 40. The lower surface of the upper member 35 and the upper surface of the lower member 36 are bonded to each other by means optionally selected, for example bonding means such as brazing.

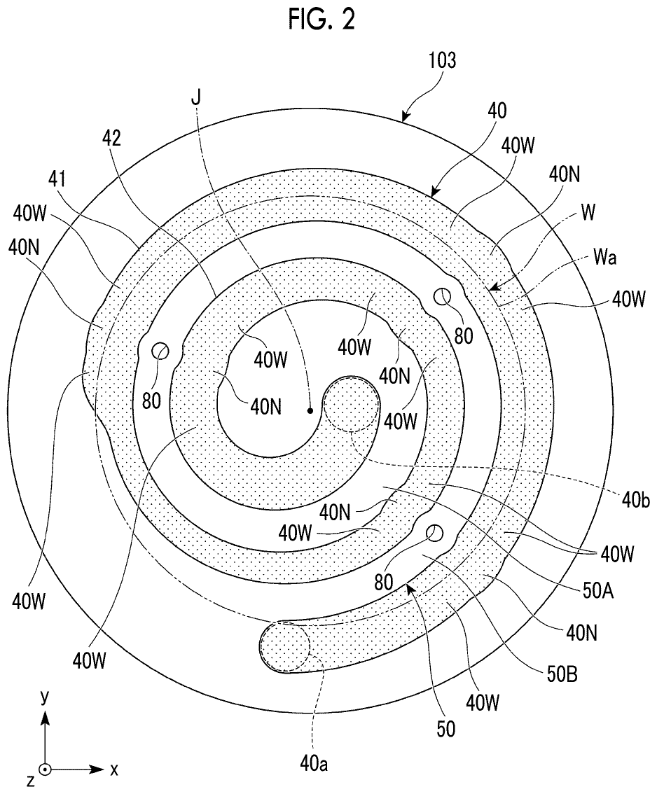

FIG. 2 is a schematic view of the refrigerant channel 40 of the present embodiment as viewed from above.

The refrigerant channel 40 of the present embodiment has a spiral shape in plan view, and more specifically, a spiral shape that spreads radially outward with respect to the central axis J. The refrigerant channel 40 of the present embodiment is continuous over the entire length. In the present embodiment, the refrigerant channel 40 is continuously separated from the central axis J while increasing the radius of curvature in the circumferential direction. The wall portion 50 is located between the channel portions of the refrigerant channel 40 that overlap each other in the radial direction. The wall portion 50 defines the refrigerant channel 40 in a spiral shape around the central axis J.

The refrigerant channel 40 has an outer peripheral channel portion 41 and an inner peripheral channel portion 42. The outer peripheral channel portion 41 is located in the outermost peripheral region of the entire length of the refrigerant channel 40, and is a region that extends by one circumference or less in the circumferential direction around the central axis J. On the other hand, the inner peripheral channel portion 42 is disposed radially inward of the outer peripheral channel portion 41 in the entire length of the refrigerant channel 40. The outer peripheral channel portion 41 and the inner peripheral channel portion 42 are connected to each other. In the present embodiment, the inflow port 40a is provided in the outer peripheral channel portion 41, and the outflow port 40b is provided in the inner peripheral channel portion 42. The inflow port 40a and the outflow port 40b are provided at the terminals or near the terminals of the refrigerant channel 40, respectively. Therefore, the refrigerant of the present embodiment flows through the refrigerant channel 40 in the order of the outer peripheral channel portion 41 and the inner peripheral channel portion 42.

The outer peripheral channel portion 41 is disposed on the outermost periphery of the refrigerant channel 40. In the present example, the outer peripheral channel portion 41 extends in an arc shape by about ¾ of a circumference with respect to the central axis J. The inflow port 40a is provided at one end of the outer peripheral channel portion 41. The other end of the outer peripheral channel portion 41 is connected to the inner peripheral channel portion 42.

The width dimension of the outer peripheral channel portion 41 is uniform over the entire length. The refrigerant channel 40 of the present embodiment has a rectangular channel cross section over the entire length and has a uniform axial dimension (depth). Therefore, the outer peripheral channel portion 41 has a uniform channel cross-sectional area over the entire length. The channel cross section may be considered as a cross section in a direction intersecting the axial direction and the extension direction of the channel.

The inner peripheral channel portion 42 has a spiral shape extending by turning about one and a half rounds around the central axis J. One end of the inner peripheral channel portion 42 is connected to the outer peripheral channel portion 41. The outflow port 40b is provided at the other end of the inner peripheral channel portion 42.

The width dimension of the inner peripheral channel portion 42 continuously decreases radially outward. Therefore, the inner peripheral channel portion 42 has a channel cross-sectional area that continuously decreases radially outward.

The wall portion 50 has a spiral shape extending by turning one circumference and about ¾ of one circumference around the central axis J. In the present embodiment, the wall portion 50 is continuously separated from the central axis J while increasing the radius of curvature in the circumferential direction. The wall portion 50 is located between and defines the inner peripheral channel portions 42 in an inner peripheral region 50A. In addition, the wall portion 50 is located between and defines the outer peripheral channel portion 41 and the inner peripheral channel portion 42 in an outer peripheral region 50B.

The radial dimension of the wall portion 50 continuously decreases as the distance from the central axis J increases. Therefore, in the refrigerant channel 40, the radial distance between channel portions disposed to overlap each other in the radial direction continuously decreases as the distance from the central axis J increases. A through-hole 80 may be disposed at the center of the radial dimension of the wall portion 50. The radial dimension of the wall portion 50 may spread once around the through-hole 80.

The electrostatic chuck device 1 has the electrostatic chucking portion 2, and the through-hole 80 that penetrates the base portion 3 in the axial direction. The through-hole 80 is formed as, for example, a lift pin insertion hole. The number of through-holes 80 can be optionally selected, and a plurality of through-holes 80 may be provided. For example, the number of through-holes 80 may be 1 to 50, 2 to 30, 3 to 10, or 4 to 6. In the present embodiment, the through-holes 80 are formed at a plurality of locations, for example, at three locations spaced apart from each other in the circumferential direction around the central axis J. The number and disposition of the through-holes 80 are not limited. A lift pin (not shown) for lifting the plate-shaped sample W is inserted into the through-hole 80 as the lift pin insertion hole. The lift pin protrudes and retracts from the through-hole 80 toward above the placement surface 11a to raise and lower the plate-shaped sample W. The shape of the through-hole 80 is, for example, circular in plan view.

The through-hole 80 may be used for other applications, such as a gas supply hole. The through-hole 80 is open to the placement surface 11a. In a case where the through-hole 80 is used as a gas supply hole, a cooling gas such as He is supplied to the through-hole 80. The cooling gas introduced from the gas supply hole flows through a gap between the placement surface 11a and the lower surface of the plate-shaped sample W and between the plurality of protruding portions 11b, thereby cooling the plate-shaped sample W.

Each through-hole 80 penetrates the base portion 3 in the axial direction. That is, the base portion 3 has the through-hole 80 and the refrigerant channel 40. The through-hole 80 penetrates a part of the wall portion 50 of the base portion 3 in the axial direction. It is preferable that the through-hole 80 and the refrigerant channel 40 are not coupled to each other. The through-hole 80 is formed between the refrigerant channels 40 adjacent to each other in the radial direction. That is, each through-hole 80 is provided in the wall portion 50 of the base portion 3. The through-hole 80 may be located between the inner peripheral channel portions 42 in the inner peripheral region 50A and/or may be located between the outer peripheral channel portion 41 and the inner peripheral channel portion 42 in the outer peripheral region 50B.

Here, in the following description, in a case where the base portion 3 is viewed in the axial direction, the radial direction of the through-hole 80 around he through-hole 80 may be referred to as a hole diameter direction.

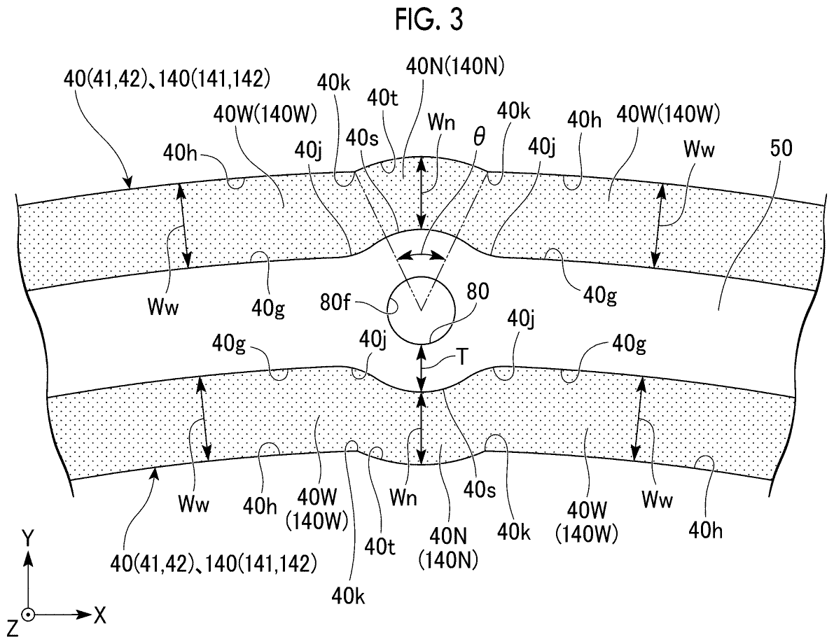

FIG. 3 is a schematic view showing a first channel portion formed around the through-hole and a second channel portion in the refrigerant channel of the embodiment. In FIG. 3, two combinations of the first channel portion and the second channel portion via the wall portion 50 are shown. The wall portion 50 has a first portion in which the through-hole 80 is provided, and a second portion which is located on both sides of the first portion and in which no through-hole is provided. In plan view, the width (a radial dimension including the through-hole) of the first portion is larger than the width of the second portion and gradually varies. The first portion has a convex outer wall. An outer surface of the first portion is an inner surface of the first channel portion, and an outer surface of the second portion is an inner surface of the second channel portion.

As shown in FIG. 3, since the refrigerant channel 40 is narrowed in width around the through-hole 80, the channel cross-sectional area is reduced. The refrigerant channel 40 has a first channel portion 40N and second channel portions 40W that are coupled to both sides of the first channel portion 40N. The length of the second channel portion 40W in the extension direction can be optionally selected, but may be, for example, about 1 to 5 times or 2 to 4 times the length of the first channel portion 40N. The first channel portion 40N is in contact with the wall portion 50 at a location where the through-hole 80 is provided. That is, the first channel portion 40N is formed on the outer side in the hole diameter direction of the through-hole 80 around the through-hole 80 at an interval from the through-hole 80. The first channel portion 40N is curved along a hole inner peripheral surface 80f of the through-hole 80 on the outer side of the through-hole 80, that is, on the outer side in the hole diameter direction. The second channel portion 40W is located on both sides of the first channel portion 40N in the extension direction of the refrigerant channel 40. The second channel portion 40W is continuous with the first channel portion 40N.

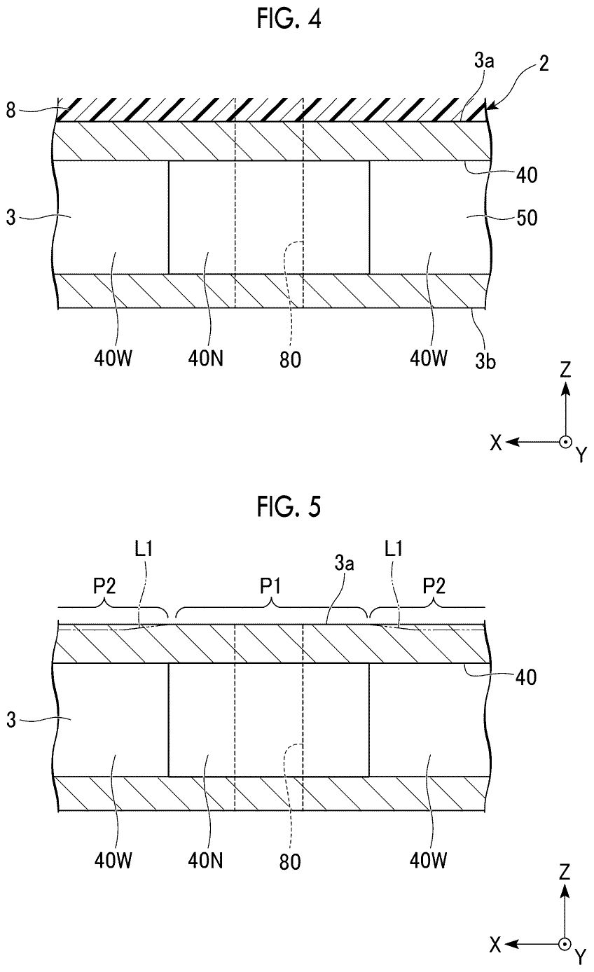

FIG. 4 is a cross-sectional view showing the first channel portion formed around the through-hole and the second channel portion coupled to the first channel portion, in the refrigerant channel of the embodiment.

As shown in FIG. 3, a width dimension Wn of the first channel portion 40N is smaller than a width dimension Ww of the second channel portion 40W. As shown in FIG. 4, the height of the first channel portion 40N and the height (depth) of the second channel portion 40W are the same. Therefore, the channel cross-sectional area of the first channel portion 40N is smaller than the channel cross-sectional area of the second channel portion 40W. As described above, since the channel cross-sectional area of the first channel portion 40N is smaller than the channel cross-sectional area of the second channel portion 40W, the flow velocity of the refrigerant flowing through the refrigerant channel 40 is higher in the first channel portion 40N having a smaller channel cross-sectional area than in the second channel portion 40W. Accordingly, heat is efficiently removed from the wall portion 50 around the through-hole 80.

Here, the channel cross-sectional area of the first channel portion 40N is preferably 0.5 times or more and less than 1.0 times the channel cross-sectional area of the second channel portion 40W. In a case where the channel cross-sectional area of the first channel portion 40N is less than 0.5 times the channel cross-sectional area of the second channel portion 40W, the pressure loss in the first channel portion 40N tends to be excessively high. On the other hand, in a case where the channel cross-sectional area of the first channel portion 40N is 1 times or more the channel cross-sectional area of the second channel portion 40W, the flow velocity of the refrigerant in the first channel portion 40N is smaller than that in the second channel portion 40W. The channel cross-sectional area of the first channel portion 40N is more preferably 0.6 times or more and less than 0.97 times the channel cross-sectional area of the second channel portion 40W, and still more preferably 0.7 times or more and less than 0.95 times the channel cross-sectional area of the second channel portion 40W. The channel cross-sectional area of the first channel portion 40N may be 0.75 times or more and less than 0.90 times the channel cross-sectional area of the second channel portion 40W or may be 0.80 times or more and less than 0.85 times the channel cross-sectional area of the second channel portion 40W.

As shown in FIG. 3, the first channel portion 40N has a first inner surface 40s and a second inner surface 40t that face each other.

The first inner surface 40s is formed on the outer side in the hole diameter direction of the through-hole 80 around the through-hole 80 at an interval from the through-hole 80. The first inner surface 40s faces the outer side in the hole diameter direction, that is, a direction away from the through-hole 80. The first inner surface 40s is formed in an arc shape formed concentrically with the hole inner peripheral surface 80f of the through-hole 80. Accordingly, the first inner surface 40s protrudes outward in the hole diameter direction with respect to an inner surface 40g of the second channel portion 40W that is located on both sides of the first channel portion 40N in the extension direction of the refrigerant channel 40.

Here, a thickness T of the wall portion 50, which is formed between the first inner surface 40s and the inner peripheral surface 80f of the through-hole 80, is optionally selected, but is preferably 1 mm or more and 10 mm or less. The thickness T of the wall portion 50 may be 1 mm or more and 3 mm or less, 3 mm or more and 6 mm or less, or 6 mm or more and 10 mm or less. In a case where the thickness T is less than 1 mm, there is a possibility that the mechanical strength of the wall portion 50 is insufficient. In addition, in a case where the thickness T exceeds 10 mm, the wall portion 50 is excessively thick, and there is a possibility that the cooling effect of the refrigerant flowing through the refrigerant channel 40 is reduced.

The second inner surface 40t is formed at an interval on the outer side in the hole diameter direction with respect to the first inner surface 40s. The second inner surface 40t faces the inner side in the hole diameter direction, that is, the side opposite to the direction away from the through-hole 80. The second inner surface 40t is formed in an arc shape formed concentrically with the hole inner peripheral surface 80f of the through-hole 80. That is, the first inner surface 40s and the second inner surface 40t are each formed concentrically with the hole inner peripheral surface 80f of the through-hole 80 as shown in FIG. 3.

Here, the first inner surface 40s and the second inner surface 40t are formed concentrically with the hole inner peripheral surface 80f of the through-hole 80, respectively, but the present invention is not limited to these examples. For example, only one of the inner surfaces may be formed concentrically. These inner surfaces may be non-concentric curved surfaces. For example, the first inner surface 40s and the second inner surface 40t may be curved with an appropriate curvature instead of being concentric with the hole inner peripheral surface 80f of the through-hole 80. In addition, from the viewpoint of making the channel cross-sectional area of the first channel portion 40N smaller than the channel cross-sectional area of the second channel portion 40W, only the first inner surface 40s may be formed to protrude outward in the hole diameter direction with respect to the inner surface 40g of the second channel portion 40W, and the second inner surface 40t may be formed to be smoothly continuous with an inner surface 40h of the second channel portion 40W without protruding.

In a case where the first inner surface 40s and the second inner surface 40t are viewed from the axial direction, an angle θ formed by a concentrically formed portion and the center of the through-hole 80 can be optionally selected, but is preferably formed in a range of 20° to 300°. The angle θ may be in a range of 20° to 45°, a range of 45° to 90°, a range of 90° to 180°, a range of 180° to 300°, or the like. In a case where the angle θ is less than 20°, particularly, the first inner surface 40s protrudes outward in the hole diameter direction, which results in a small contribution to the reduction in the channel cross-sectional area of the first channel portion 40N. In a case where the angle θ exceeds 300°, the wall portion 50 between the hole inner peripheral surface 80f of the through-hole 80 and the first inner surface 40s is continuous in the circumferential direction around the through-hole 80 and has a shape close to a cylindrical shape.

Accordingly, the rigidity of the wall portion 50 in the axial direction around the through-hole 80 is increased. In this case, as shown by a two-dot chain line L1 in FIG. 5, in a case where a plane such as the support surface 3a of the base portion 3 is cut by a machine tool, a portion P1 of the wall portion 50 surrounding the through-hole 80 has a smaller dimension to be downward bent due to the stress acting from the machine tool than a portion P2, around the portion P1, where the refrigerant channel 40 is formed below the upper member 35. In the portion P2, since the upper member 35 is cut in a state of being bent downward due to the stress from the machine tool, the cutting amount of the upper member 35 is small. On the other hand, the portion P1 of the wall portion 50 around the through-hole 80 has a small dimension to be downward bent due to the stress from the machine tool, and the cutting amount thereof increases accordingly. As a result, in a case where the bending of the portion P2 in which the refrigerant channel 40 is formed is restored after the completion of the cutting, the support surface 3a is lower in the portion P1 of the wall portion 50 around the through-hole 80 than in the portion P2 in which the refrigerant channel 40 is formed. As a result, there is a possibility that a slight gap is generated between the portion P1 of the wall portion 50 around the through-hole 80 and the plate-shaped sample W in a state where the plate-shaped sample W is placed on the support surface 3a.

On the other hand, by setting the angle θ to be less than 300°, the occurrence of the above-described event can be suppressed.

In addition, as shown in FIG. 3, in the second channel portion 40W on both sides of the first channel portion 40N in the extension direction of the refrigerant channel 40, a connection surface 40j that is curved in an arc shape as viewed in the axial direction is formed between the inner surface 40g connected to the first inner surface 40s and the first inner surface 40s. In addition, a connection surface 40k that is curved in an arc shape as viewed in the axial direction is also formed between the inner surface 40h of the second channel portion 40W connected to the second inner surface 40t and the second inner surface 40t.

### Effects of Embodiment

In the electrostatic chuck device 1 of the present embodiment, the refrigerant channel 40 has the first channel portion 40N that is formed at an interval on the outer side of the through-hole 80 in the hole diameter direction, and the second channel portion 40W that is located on both sides of the first channel portion 40N in the extension direction of the refrigerant channel 40. The channel cross-sectional area of the first channel portion 40N is smaller than the channel cross-sectional area of the second channel portion 40W. Accordingly, the flow velocity of the refrigerant in the refrigerant channel 40 is increased in the first channel portion 40N having a smaller channel cross-sectional area than the second channel portion 40W having a larger channel cross-sectional area. Accordingly, the cooling performance in the first channel portion 40N is improved. A lift pin is inserted into the through-hole 80 as necessary, and the through-hole 80 is optionally filled with a cooling gas such as He. In order to electrically insulate the through-hole 80 from a base member, an insulating component is preferably inserted into the through-hole 80. However, as a result, the thermal insulation performance in the through-hole 80 is increased, and the cooling performance is decreased. As a result, the cooling effect of the refrigerant around the through-hole 80 decreases, and the temperature is likely to rise. On the other hand, by making the channel cross-sectional area of the first channel portion 40N smaller than the channel cross-sectional area of the second channel portion 40W, it is possible to provide the electrostatic chuck device 1 having high temperature uniformity.

The first channel portion 40N of the present embodiment has a smaller width dimension in the direction intersecting the axial direction and the extension direction than the second channel portion 40W. As described above, the channel cross-sectional area of the first channel portion 40N can be easily made smaller than the channel cross-sectional area of the second channel portion 40W.

The channel cross-sectional area of the first channel portion 40N of the present embodiment is preferably 0.5 times or more and less than 1.0 times the channel cross-sectional area of the second channel portion 40W. Accordingly, by reducing the channel cross-sectional area of the first channel portion 40N, the temperature uniformity can be efficiently increased.

The first channel portion 40N of the present embodiment has the first inner surface 40s and the second inner surface 40t, and the first inner surface 40s is preferably formed in an arc shape formed concentrically with the hole inner peripheral surface 80f of the through-hole 80. Accordingly, the thickness T of the wall portion 50 between the first inner surface 40s and the hole inner peripheral surface 80f can be made constant, and the temperature uniformity can be improved.

The second inner surface 40t of the present embodiment is preferably formed in an arc shape formed concentrically with the hole inner peripheral surface 80f of the through-hole 80. Accordingly, since the first inner surface 40s and the second inner surface 40t are concentrically formed, the first channel portion 40N can be easily formed by a machine tool.

The first inner surface 40s and the second inner surface 40t of the present embodiment are preferably formed in a range of 20° to 300° around the center of the through-hole 80 as viewed from the axial direction. Accordingly, it is possible to suppress the rigidity of the wall portion 50 around the through-hole 80 from being excessively increased while reducing the channel cross-sectional area of the first channel portion 40N.

The connection surface 40j is formed between the first inner surface 40s of the present embodiment and the inner surface 40g connected to the first inner surface 40s. It is preferable that the connection surface 40j is a curved surface in plan view. Accordingly, in the flow of the refrigerant in the refrigerant channel 40, it is possible to suppress the occurrence of peeling at a boundary portion between the first inner surface 40s and the inner surface 40g. Accordingly, the occurrence of a portion where the cooling efficiency is low around the through-hole 80 is suppressed, and the temperature uniformity is improved.

The thickness of the wall portion 50 formed between the inner peripheral surface of the through-hole 80 and the first inner surface 40s in the present embodiment is preferably 1 mm or more and 10 mm or less. Accordingly, the decrease in the temperature uniformity is suppressed while ensuring the strength of the wall portion 50.

In addition, the inner peripheral channel portion 42 of the present embodiment is disposed radially inward of the outer peripheral channel portion 41. The base portion 3 keeps the temperature of the plate-shaped sample W constant by actively cooling the region of the electrostatic chucking portion 2 that overlaps with the plate-shaped sample W as viewed from the axial direction. According to the present embodiment, the inner peripheral channel portion 42 and the outer peripheral channel portion 41 are provided and the respective channel configurations are optimized, so that the temperature uniformity of the electrostatic chucking portion 2 can be improved up to the vicinity of an outer edge Wa of the plate-shaped sample W.

### Modification Example of Embodiment

In the above-described embodiment, the refrigerant channel 40 includes the outer peripheral channel portion 41 and the inner peripheral channel portion 42. However, the present invention is not limited thereto.

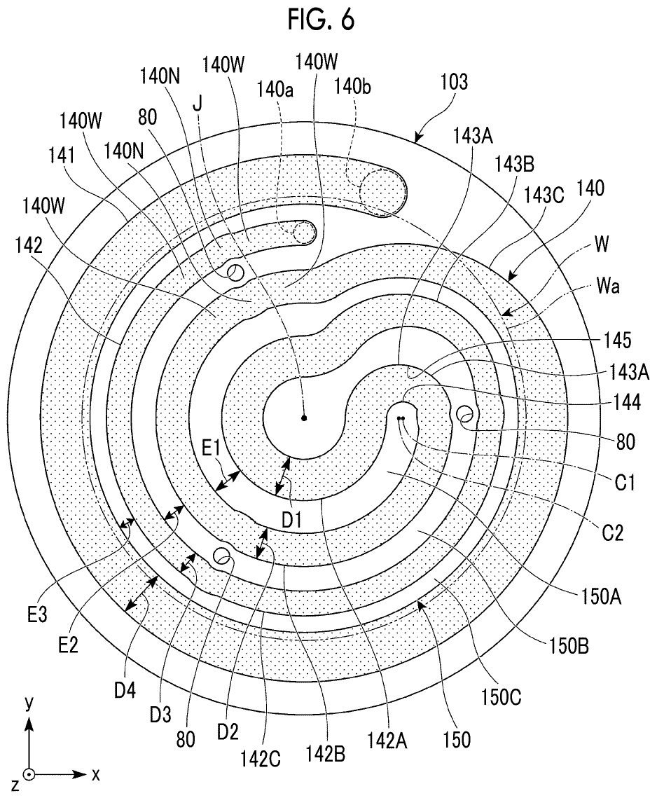

FIG. 6 is a schematic view showing a refrigerant channel 140 of a modification example of the embodiment. The refrigerant channel 140 of the second embodiment will be described below with reference to FIG. 3. In addition, components similar to those of the above-described embodiment are denoted by the same reference numerals, and detailed description thereof is omitted.

### Channel

The refrigerant channel 140 of the present embodiment has a double spiral shape that is folded near the central axis J. The double spiral of the refrigerant channel 140 spreads radially outward with respect to the central axis J. The refrigerant channel 140 of the present embodiment is continuous over the entire length. The refrigerant channel 140 of the present embodiment has a rectangular channel cross section over the entire length and has a uniform axial dimension. A wall portion 150 is located between the radially overlapping portions of the refrigerant channel 140. The wall portion 150 defines the refrigerant channel 140 in a spiral shape around the central axis J.

The refrigerant channel 140 has an outer peripheral channel portion 141 having a constant width and an inner peripheral channel portion 142 disposed radially inward of the outer peripheral channel portion 141. The outer peripheral channel portion 141 and the inner peripheral channel portion 142 are connected to each other. In the present embodiment, an inflow port 140a is provided in the inner peripheral channel portion 142, and an outflow port 140b is provided in the outer peripheral channel portion 141.

Therefore, the refrigerant of the present embodiment flows through the refrigerant channel 40 in the order of the inner peripheral channel portion 142 and the outer peripheral channel portion 141.

The outer peripheral channel portion 141 is disposed at the outermost periphery of the refrigerant channel 140. The outer peripheral channel portion 141 extends in an arc shape, for example, about 6/10 to 9/10 of a circumference or about 7/10 to 8/10 of a circumference, and specifically, about ¾ of a circumference with respect to the central axis J. The inner peripheral channel portion 142 is connected to one end of the outer peripheral channel portion 141. The outflow port 140b is provided at the other end of the outer peripheral channel portion 141. In addition, it is preferable that the outer peripheral channel portion 141 overlaps the outer edge Wa of the plate-shaped sample W as viewed from the axial direction. The outer peripheral channel portion 141 has a uniform width dimension over the entire length as described above. Therefore, the outer peripheral channel portion 141 has a uniform channel cross-sectional area over the entire length.

The inner peripheral channel portion 142 has a first arc portion 142A, a second arc portion 142B, and a third arc portion 142C, which have a constant width in this order from the inside. The inner peripheral channel portion 142 further has a first connecting portion 143A, a second connecting portion 143B, and a third connecting portion 143C that connect the arc portions to each other or connect the outer peripheral channel portion 141 and the second arc portion 142B to each other. The first arc portion 142A, the second arc portion 142B, and the third arc portion 142C extend in an arc shape around the central axis J. The first arc portion 142A, the second arc portion 142B, and the third arc portion 142C are disposed concentrically around the central axis J.

The first arc portion 142A is located at the innermost periphery of the inner peripheral channel portion 142. The first arc portion 142A extends in an arc shape about ¾ of a circumference around the central axis J. The first connecting portion 143A is connected to one end of the first arc portion 142A. The second connecting portion 143B is connected to the other end of the first arc portion 142A. The width dimension of the first arc portion 142A is uniform over the entire length. Therefore, the first arc portion 142A has a uniform channel cross-sectional area over the entire length.

The second arc portion 142B is located radially outward of the first arc portion 142A. The second arc portion 142B is located between the first arc portion 142A and the third arc portion 142C in the radial direction. The second arc portion 142B extends in an arc shape about ¾ of a circumference around the central axis J. The first connecting portion 143A is connected to one end of the second arc portion 142B. The third connecting portion 143C is connected to the other end of the second arc portion 142B. The width dimension of the second arc portion 142B is uniform over the entire length. Therefore, the second arc portion 142B has a uniform channel cross-sectional area over the entire length.

The third arc portion 142C is located radially outward of the second arc portion 142B. The third arc portion 142C is located between the second arc portion 142B and the outer peripheral channel portion 141 in the radial direction. The third arc portion 142C extends in an arc shape about ¾ of a circumference around the central axis J.

The second connecting portion 143B is connected to one end of the third arc portion 142C. In addition, the inflow port 140a is provided at the other end of the third arc portion 142C. The width dimension of the third arc portion 142C is uniform over the entire length. Therefore, the third arc portion 142C has a uniform channel cross-sectional area over the entire length.

A width dimension D2 of the second arc portion 142B is smaller than a width dimension D1 of the first arc portion 142A (D2<D1). In addition, a width dimension D3 of the third arc portion 142C is smaller than the width dimension D2 of the second arc portion 142B (D3<D2). That is, among the plurality of arc portions 142A, 142B, and 142C, the arc portion located on the radially outer side with respect to the other arc portions has a smaller radial dimension (width) than the other arc portions located on the radially inner side (D3<D2<D1). Furthermore, a width dimension D4 of the outer peripheral channel portion 141 is larger than the width dimension of the inner peripheral channel portion 142 at any position (D4>D1, D4>D2, D4>D3). That is, the width dimension D4 of the outer peripheral channel portion 141 is larger than the width dimensions D1, D2, and D3 of the inner peripheral channel portion 142.

The first connecting portion 143A connects one end of the first arc portion 142A and one end of the second arc portion 142B. In the present embodiment, one end of the first arc portion 142A and one end of the second arc portion 142B are disposed side by side in the radial direction. The first connecting portion 143A connects the first arc portion 142A and the second arc portion 142B to be folded back in a hairpin shape, that is, in a U-shape. The width dimension of the first connecting portion 143A gradually decreases from the end portion on the first arc portion 142A side toward the end portion on the second arc portion 142B side.

The first connecting portion 143A is bent and has side surfaces facing each other, that is, an inner corner surface 144 and an outer corner surface 145. The inner corner surface 144 is a semicircular arc surface around a center point C1. In addition, the outer corner surface 145 is a semicircular arc surface around a center point C2. The radius of curvature of the inner corner surface 144 is smaller than the radius of curvature of the outer corner surface 145. In addition, the center point C1 of the inner corner surface 144 and the center point C2 of the outer corner surface 145 are disposed at different positions. That is, the inner corner surface 144 and the outer corner surface 145 are arc surfaces having different centers. Accordingly, the first connecting portion 143A smoothly connects the first arc portion 142A and the second arc portion 142B having different width dimensions.

The second connecting portion 143B connects the other end of the first arc portion 142A and one end of the third arc portion 142C. The second connecting portion 143B connects the first arc portion 142A and the third arc portion 142C to be folded back like a hairpin. The second connecting portion 143B extends along the first connecting portion 143A with a larger radius of curvature than the first connecting portion 143A.

The width dimension of the second connecting portion 143B gradually decreases from the end portion on the first arc portion 142A side toward the end portion on the third arc portion 142C side. The second connecting portion 143B smoothly connects the first arc portion 142A and the third arc portion 142C by having an inner corner surface and an outer corner surface having the same relationship as the first connecting portion 143A.

The third connecting portion 143C connects the other end of the second arc portion 142B and the one end of the outer peripheral channel portion 141. The third connecting portion 143C connects the second arc portion 142B and the outer peripheral channel portion 141 to be folded back in a hairpin shape. The third connecting portion 143C extends along the second connecting portion 143B with a larger radius of curvature than the second connecting portion 143B. The third connecting portion 143C gradually increases in width dimension from the end portion on the second arc portion 142B side toward the end portion on the outer peripheral channel portion 141 side. The third connecting portion 143C smoothly connects the second arc portion 142B and the outer peripheral channel portion 141 by having an inner corner surface and an outer corner surface having the same relationship as the first connecting portion 143A.

### Wall Portion

The wall portion 150 has a first arc wall 150A, a second arc wall 150B, and a third arc wall 150C, each of which has a constant width, in order from the inside. The first arc wall 150A, the second arc wall 150B, and the third arc wall 150C extend in an arc shape around the central axis J. In addition, the first arc wall 150A, the second arc wall 150B, and the third arc wall 150C are disposed concentrically around the central axis J.

The first arc wall 150A extends in an arc shape about ¾ of a circumference around the central axis J. The first arc wall 150A is located radially between and defines the first arc portion 142A and the second arc portion 142B. The radial dimension of the first arc wall 150A is uniform over the entire length.

The second arc wall 150B extends in an arc shape about ¾ of a circumference around the central axis J. The second arc wall 150B is located radially between and defines the second arc portion 142B and the third arc portion 142C. The radial dimension of the second arc wall 150B is uniform over the entire length.

The third arc wall 150C extends in an arc shape about ¾ of a circumference around the central axis J. The third arc wall 150C is located between and defines the third arc portion 142C and the outer peripheral channel portion 141 in the radial direction. The radial dimension of the third arc wall 150C is uniform over the entire length.

A radial dimension E2 of the second arc wall 150B is smaller than a radial dimension E1 of the first arc wall 150A (E2<E1). In addition, a radial dimension E3 of the third arc wall 150C is smaller than the radial dimension E2 of the second arc wall 150B (E3<E2). That is, among the plurality of arc walls 150A, 150B, and 150C, the arc wall located radially outward of the other arc walls has a smaller radial dimension than the other arc walls (E3<E2<E1). The wall portion 150 also preferably has a circular wall portion located at the center surrounded by the first arc portion 142A, a substantially semicircular wall portion surrounded by the first connecting portion 143A, a wall portion located between the first connecting portion 143A and the second connecting portion 143B, and a wall portion located between the second connecting portion 143B and the third connecting portion 143C.

The refrigerant channel 140 of such a modification example may have a first channel portion 140N having the above-described relationship and a second channel portion 140W connected to the first channel portion 140N in the vicinity of the through-hole 80 as in the above-described embodiment. With such a configuration, the channel cross-sectional area is reduced around the through-hole 80. Therefore, the flow velocity of the refrigerant in the refrigerant channel 140 is increased in the first channel portion 140N having a smaller channel cross-sectional area than the second channel portion 140W having a larger channel cross-sectional area, and the cooling performance in the first channel portion 40N is improved. As a result, it is possible to provide the electrostatic chuck device 1 having high temperature uniformity.

In addition, according to the base portion 103 of the present modification example, as in the above-described embodiment, the flow velocity increases as the distance from the central axis J increases as the channel cross-sectional area of the inner peripheral channel portion 142 decreases as the distance from the central axis J increases. As a result, the cooling capability in a region away from the central axis J can be increased, and the temperature uniformity in the placement surface 11a of the electrostatic chucking portion 2 can be increased. In addition, according to the base portion 103 of the present modification example, as in the above-described embodiment, the channel cross-sectional area of the outer peripheral channel portion 141 is larger than the channel cross-sectional area of the inner peripheral channel portion 142. Accordingly, the electrostatic chucking portion 2 can be sufficiently cooled.

Although the preferred embodiment according to the present invention has been described above with reference to the accompanying drawings, it goes without saying that the present invention is not limited to such an example. The various shapes, combinations, and the like of the constituent members shown in the above-described example are merely examples, and various modifications can be made based on design requirements and the like without departing from the gist of the present invention.

For example, in the above-described embodiment and modification example, the channel cross-sectional area of the inner peripheral channel portions 42 and 142 is set to be smaller as the distance from the central axis J increases, and the channel cross-sectional area of the outer peripheral channel portions 41 and 141 is set to be larger than the channel cross-sectional area of the inner peripheral channel portions 42 and 142. However, the present invention is not limited thereto. For example, even in a case where the channel cross-sectional areas of the outer peripheral channel portions 41 and and the inner peripheral channel portions 42 and 142 are constant, the configuration as described above may be applied to the periphery of the through-hole 80.

In addition, although a case where the channel cross section of the refrigerant channel has a rectangular shape and the axial dimension is uniform over the entire length has been described, the cross-sectional shape of the refrigerant channel is not limited to the above-described embodiment. For example, the refrigerant channel may vary in the channel cross-sectional area by varying the axial dimension.

### REFERENCE SIGNS LIST

1 Electrostatic chuck device
2 Electrostatic chucking portion
3, 103 Base portion
3a Support surface
3b Bottom surface
4 Adhesive
5 Heater element
8 Adhesive layer
11 Placement plate
11a Placement surface
11b Plurality of protruding portions
12 Supporting plate
13 Electrostatic attraction electrode
14 Insulating material layer
17 Peripheral wall
31g Recessed groove
35 Upper member
36 Lower member
40, 140 Refrigerant channel
40a, 140a Inflow port of channel
40b, 140b Outflow port of channel
40g, 40h Inner surface of second channel portion
40j, 40k Connection surface between first channel portion and second channel portion
40N, 140N First channel portion
40W, 140W Second channel portion
40s First inner surface of first channel portion
40t Second inner surface of first channel portion
41, 141 Outer peripheral channel portion
42, 142 Inner peripheral channel portion
50, 150 Wall portion
50A Inner peripheral region
50B Outer peripheral region
80 Through-hole
80f Hole inner peripheral surface
142A First arc portion (channel portion)
142B Second arc portion (channel portion)
142C Third arc portion (channel portion)
143A First connecting portion (channel portion)
143B Second connecting portion (channel portion)
143C Third connecting portion (channel portion)
144 Inner corner surface of first connecting portion
145 Outer corner surface of first connecting portion
150 Wall portion
150A First arc wall (wall portion)
150B Second arc wall (wall portion)
150C Third arc wall (wall portion)
C1, C2 Center point
D1 Width dimension of first arc portion
D2 Width dimension of second arc portion
D3 Width dimension of third arc portion
D4 Width dimension of outer peripheral channel portion
El Radial dimension of first arc wall
E2 Radial dimension of second arc wall
E3 Radial dimension of third arc wall
Dx Axial dimension of refrigerant channel
J Central axis
L1 Two-dot chain line
P1 Wall portion around through-hole
P2 Portion where refrigerant channel is formed
T Thickness
W Plate-shaped sample
Wa Outer edge of plate-shaped sample
Wn Width dimension
Ww Width dimension
θ Angle around center of through-hole

1. An electrostatic chuck device comprising:
a plate-shaped electrostatic chucking portion that has a placement surface on which a plate-shaped sample is placed and that has an electrostatic attraction electrode provided therein; and
a base portion that has a disk shape around a central axis and that supports the electrostatic chucking portion from a side opposite to the placement surface on a support surface of the base portion,
wherein the base portion has
at least one through-hole that penetrates the base portion in an axial direction of the central axis, and
a refrigerant channel that is provided inside the base portion and extends along the support surface,
the refrigerant channel has
a first channel portion, and
a second channel portion that is coupled to both ends of the first channel portion,
the first channel portion is formed on an outer side in a hole diameter direction of the through-hole around the through-hole at an interval from the through-hole,
the second channel portion is located on both sides of the first channel portion in an extension direction of the refrigerant channel, and
a channel cross-sectional area of the first channel portion is smaller than a channel cross-sectional area of the second channel portion.

2. The electrostatic chuck device according to claim 1,
wherein the first channel portion has a smaller width dimension in a direction intersecting the axial direction and the extension direction than the second channel portion.

3. The electrostatic chuck device according to claim 1,
wherein the channel cross-sectional area of the first channel portion is 0.5 times or more and less than 1.0 times the channel cross-sectional area of the second channel portion.

4. The electrostatic chuck device according to claim 1,
wherein the first channel portion has a first inner surface and a second inner surface that face each other,
the first inner surface is formed on the outer side in the hole diameter direction of the through-hole at an interval from the through-hole and faces the outer side in the hole diameter direction,
the second inner surface is formed on the outer side in the hole diameter direction with respect to the first inner surface at an interval from the first inner surface and faces an inner side in the hole diameter direction, and
the first inner surface is formed in an arc shape formed concentrically with a hole inner peripheral surface of the through-hole.

5. The electrostatic chuck device according to claim 4,
wherein the second inner surface is formed in an arc shape formed concentrically with the hole inner peripheral surface of the through-hole.

6. The electrostatic chuck device according to claim 5,
wherein the first inner surface and the second inner surface are formed in a range of 20° to 300° around the through-hole as viewed in the axial direction.

7. The electrostatic chuck device according to claim 4,
wherein in the second channel portion that is located on at least one side of the first channel portion in the extension direction of the refrigerant channel, a connection surface curved in an arc-shape as viewed in the axial direction is formed between an inner surface of the second channel portion connected to the first inner surface and the first inner surface.

8. The electrostatic chuck device according to claim 4,
wherein a thickness of a wall portion formed between the hole inner peripheral surface of the through-hole and the first inner surface is 1 mm or more and 10 mm or less.

9. The electrostatic chuck device according to claim 1,
wherein the refrigerant channel has a continuous spiral shape in plan view,
the base portion further includes a wall portion that partitions the refrigerant channel,
the through-hole is circular in plan view and penetrates at least a part of the wall portion in the axial direction,
the wall portion includes a first portion in which the through-hole is provided and a second portion which is located on both sides of the first portion and in which no through-hole is provided,
a width of the first portion is larger than a width of the second portion in plan view,
the width of the first portion varies gradually, and
a side surface of the first portion forms an inner surface of the first channel portion, and a side surface of the second portion forms an inner surface of the second channel portion.
